(19) United States
(12) Patent Application Publication
(10) Pub. No.: US 2026/0160580 A1
(43) Pub. Date: Jun. 11, 2026

(54) Sensor Assembly for Detecting a Pedaling Frequency of a Bicycle

(71) Applicant: Robert Bosch GmbH, Stuttgart (DE)

(72) Inventors: Eduard Jankewitsch, Tuebingen (DE); Tobias Haug, Bodelshausen (DE); Thomas Schirling, Balingen (DE); Marcel von Olnhausen, Kirchheim (DE); Roman Walther, Ludwigsburg (DE)

(21) Appl. No.: 19/411,750

(22) Filed: Dec. 8, 2025

(30) Foreign Application Priority Data
Dec. 10, 2024 (DE) 10 2024 211 759.5

(51) Int. Cl. G01D 5/16; B62J 45/413; B62J 45/421; G01R 33/09

(52) U.S. Cl. CPC G01D 5/16; B62J 45/413; B62J 45/421; G01R 33/091

(57) ABSTRACT

A sensor assembly for detecting a pedaling frequency of a bicycle includes a sensor and a sensor mount configured to hold the sensor. The sensor is configured to detect a relative movement of a signal element to the sensor. The sensor mount includes a first holding element and a second holding element. The first holding element is configured to be attached to the bicycle. The second holding element is attached to the first holding element. The second holding element is configured to hold the sensor.

This application claims priority under 35 U.S.C. § 119 to patent application no. DE 10 2024211 759.5, filed on Dec. 10, 2024 in Germany, the disclosure of which is incorporated herein by reference in its entirety.

### BACKGROUND

The present disclosure relates to a sensor assembly for detecting a pedaling frequency of a bicycle, a drive assembly of a bicycle, and a bicycle.

Sensor assemblies are known by way of which a pedaling frequency can be detected when pedal actuating a bicycle. For example, the detected pedaling frequencies may be detected in an informative manner for communicating to the rider. Alternatively or additionally, pedaling frequencies may be used to control certain functions. For example, in the case of electric bicycles, actuation of the motor can also be dependent on the pedaling frequency and/or the pedal operation. Known sensor assemblies are often simply constructed and have varying levels of accuracy. For example, the use of Hall sensors for detecting the pedaling frequency is known.

### SUMMARY

In contrast, the sensor assembly according to the disclosure with the features set forth below is characterized in that a particularly precise detection of pedaling frequencies of a bicycle can be enabled by way of a particularly simple and cost-efficient design. In particular, a particularly simple, time-efficient and cost-efficient assembly of the sensor assembly can take place. This is achieved according to the present disclosure by a sensor assembly for detecting a pedaling frequency of a bicycle, comprising a sensor and a sensor bracket. The sensor is configured to detect a relative movement of a signal element to the sensor. Preferably, the sensor is a magnetoresistive sensor, which is in particular configured to detect variable magnetic fields generated, for example, by the signal element. This sensor mount comprises a first holding element and a second holding element. The first holding element and the second holding element are preferably configured as separate components. Alternatively, the first holding element and the second holding element may also be configured together as an integral component. The first holding element is configured to be attached to the bicycle, particularly to a bicycle component of the bicycle. The second holding element is attached to the first holding element. The second holding element is configured to hold the sensor.

In particular, the second holding element is configured to hold the sensor by way of a clamping connection. Particularly preferably, the second holding element is configured as a sleeve within which the sensor is arranged.

In other words, a sensor assembly is provided comprising the sensor and a sensor mount by way of which the sensor is attached to the bicycle and relative to the signal element, which is preferably arranged on the bicycle. The sensor bracket comprises a first holding element and a second holding element, wherein the first holding element is configured, in particular for direct attachment to the bicycle, and wherein the second holding element is attached to the first holding element. The sensor is thereby held by the second holding element.

The sensor assembly is thus characterized by the fact that a simple and inexpensively manufactured design can enable a reliable and robust mounting of the sensor. Particularly advantageous is a simplified assembly of the sensor assembly on the bicycle. In particular, the various parts of the sensor assembly, i.e., the sensor, as well as the first holding element and the second holding element, can be mounted at least partially individually, thereby enabling a simple assembly with particularly high flexibility for a variety of bicycles and bicycle geometries. For example, the first holding element can first be mounted independently on the bicycle, wherein the second holding element can subsequently be attached to the first holding element. The sensor can, for example, already be held in the second holding element, or alternatively be inserted into the second holding element later. Further advantageous is a simple and inexpensive adjustability of the sensor mount to different bicycles. For example, the first holding element and the second holding element may be easily adjusted independently in geometry for the particular intended use.

Furthermore, a sensor mount for a sensor is disclosed, wherein the sensor is configured to detect a relative movement of a signal element to the sensor. In particular, the sensor is thus provided for detecting a pedaling frequency of a bicycle. The sensor mount is configured to hold the sensor. The sensor mount includes a first holding element and a second holding element. The first holding element is configured to attach to the bicycle. The second holding element is attached to the first holding element. The second holding element is configured to hold the sensor. In particular, the sensor is held by way of the second holding element by a clamping connection.

Preferably, the first holding element comprises two recesses, and the second holding element comprises two protruding wing elements that engage in the recesses of the first holding element. Particularly preferably, the two recesses of the first holding element are arranged at orthogonal holding regions of the first holding element. Further preferably, the wing elements of the second holding element extend along orthogonal wing axes. Preferably, at least one of the two recesses of the first holding element is configured as a groove. Particularly preferably, both recesses are each configured as a groove, which preferably extend parallel to each other. A variety of protruding elements can preferably be considered as wing elements, for example round or square pins. Particularly preferably, the wing elements have elongated geometry corresponding to the recesses. In other words, corresponding engaging elements are provided on the first holding element and on the second holding element by way of which the two holding elements can be held together. In the attached state, the wing axes of the wing elements are respectively orthogonal to the respective holding region in which the respective wing element engages. A particularly advantageous assembly of the second holding element on the first holding element can thus take place. In detail, the second holding element can thereby be clipped laterally to the first holding element. For this purpose, one of the wing elements can first be inserted into one of the recesses and subsequently, in particular by way of a rotational movement, the second wing element can be clipped into the second recess in a positively locked manner. Preferably, at least one of the recesses is configured such that the first holding element adjacent to this recess comprises a resiliently compliant spring region, in particular to facilitate clipping. Thus, a mounting of the sensor assembly can be made particularly simple and advantageous even in very confined spaces on the bicycle.

Preferably, the second holding element is attached to the first holding element by way of an oblong hole and by way of a fixing element arranged in the oblong hole. Preferably, the oblong hole is formed in the second holding element. Alternatively, the oblong hole is configured in the first holding element. Preferably, the fixing element is formed as a screw. In particular, the oblong hole extends along a direction parallel to a sensor axis. By way of the oblong hole, a particularly simple and flexible arrangement and assembly of the parts of the sensor assembly can be made possible. In particular, the second holding element can thereby be moved with the sensor relative to the first holding element and thus relative to the bicycle, in order to be able to flexibly adjust a distance between the sensor and the signal element, for example.

Furthermore, a first holding element of a sensor mount for a sensor configured to detect relative movement of a signal element to the sensor is disclosed and, in particular, is thus provided for detecting a pedaling frequency of a bicycle. The first holding element is configured to be attached to the bicycle. Preferably, the first holding element is further configured for attaching a second holding element to the first holding element, wherein the second holding element is provided for holding the sensor.

Preferably, the first holding element comprises an annular attachment region by way of which the first holding element, and thus in particular the sensor bracket, is coaxially attachable at a bottom bracket arrangement of the bicycle to an output shaft. Preferably, the annular attachment region comprises an axial wall thickness of a bottom bracket spacer disc. In particular, an annular disc, which may be referred to as a “spacer”, is considered a bottom bracket spacer, for example, and which is provided as a spacer, which is arranged directly on a bottom bracket of the bicycle. In other words, the first holding element is suited to selectively directly replace a bottom bracket spacer of a bicycle. A particularly simple and inexpensive design of a sensor assembly, and in particular additional or subsequent equipping of the bicycle with such a sensor assembly, can be made possible. In particular, essentially no modifications are necessary on the bicycle, except for the replacement of the bottom bracket spacer by the first holding element. A second holding element and a sensor can preferably be mounted on the further sub-areas of the first holding element.

Particularly preferably, the first holding element is configured as a, preferably multiple, angled component, in particular sheet metal, and/or comprises at least two orthogonal contact surfaces. In particular, one of the abutment surfaces is an axial end face of the annular attachment region, in particular for direct abutment on a bottom bracket of the bicycle. Preferably, a second abutment surface is parallel to a radial direction of the annular attachment region. Preferably, the second abutment surface is configured for the attachment of a second holding element and/or the sensor. Particularly preferably, the first holding element further comprises a third abutment surface, which is orthogonal to the first abutment surface and orthogonal to the second abutment surface. In particular, the third abutment surface is arranged substantially tangentially with respect to the annular attachment region. Particularly preferably, the second abutment surface and the third abutment surface each comprise a recess, which can preferably be engaged by wing elements of a second holding element. Particularly when the first holding element is configured as a sheet metal, a particularly robust construction can thus be made possible with simple and cost-efficient manufacture. By way of the angled design, a high bending stiffness of the first holding element can be enabled in order to allow reliable precise positioning of the sensor, which allows for particularly precise determinations of the pedaling frequency.

Further disclosed is a second holding element of a sensor mount, for a sensor configured to detect relative movement of a signal element to the sensor, and, in particular, that is thus provided for detecting a pedaling frequency of a bicycle. The second holding element is configured to hold the sensor. Preferably, the second holding element is configured to hold the sensor by a clamping connection.

In particular, the second holding element is configured to hold the sensor at different sliding positions. In other words, the second holding element allows the sensor to be fixed along a sensor axis, along which the sensor can be positioned as desired within the holding element.

Preferably, the second holding element is configured as a sleeve within which the sensor can be arranged. That is, the second holding element may circumferentially encompass the sensor. Particularly preferably, the second holding element is configured as a slotted sleeve in order to enable clamping fixation of the sensor in a particularly simple and cost-efficient manner.

Preferably, the second holding element comprises at least one axial securing element, which limits axial displacement of the sensor in at least one direction. Preferably, the at least one axial securing element is arranged at an axial end of the preferably sleeve-shaped second holding element and projects radially inward into a recess of the second holding element, in which the sensor can be arranged. This prevents axial displacement of the sensor, and in particular prevents the sensor falling out of the second holding element.

Preferably, the second holding element is configured for, in particular, radially clamping attachment of the sensor. Preferably, the second holding element is configured as a slotted sleeve for this purpose, within which the sensor can be arranged. This enables a particularly flexible and precise positioning of the sensor by way of a simple and cost-efficient design.

Preferably, the sensor is substantially cylindrical and preferably has an anti-rotation device. In particular, the sensor extends along substantially a sensor axis. Preferably, the anti-rotation device comprises a flattened jacket region on a jacket surface of the sensor, which preferably extends in the axial direction. Preferably, the flattened jacket region extends within an angular range of at least 10°, preferably a maximum of 30°, starting from the sensor axis. The sensor can thus be manufactured in a simple and inexpensive manner and have a particularly space-saving and easy-to-mount geometry. Due to the flattened jacket region, a precisely defined positioning of the sensor, in particular in the second holding element, can be enabled with regard to a rotation about the sensor axis.

Particularly preferably, the sensor and the second holding element each comprise corresponding positive locking elements which interlock positively with respect to a circumferential direction of the second holding element and/or the sensor, for rotational positioning of the sensor. In other words, matching form-fit elements are provided on the sensor and on the second holding element, which, when the sensor is arranged in the second holding element, cause the sensor to be positioned precisely and unambiguously with respect to rotation about the sensor axis due to the form fit. This ensures precise positioning during assembly and over the course of the service life in a simple and targeted manner.

Further disclosed is a drive assembly of a bicycle comprising an output element and a signal element. The output element is configured to engage a transmission element of the bicycle. The signal element is attached to the output element in a rotationally fixed manner. The signal element is configured as a signal disc, preferably a perforated disc. Preferably, the output element is a chain sprocket, which is preferably configured to engage with a bicycle chain as a transmission element. In particular, a partially planar, disc-shaped element is considered to be a signal disc, which is fixedly attached to the output element. Particularly preferably, the signal disc can be configured as a perforated disc, which has a plurality of holes evenly distributed around the circumference. The signal disc can thereby be detected by way of a sensor in order to be able to detect a rotation of the output element. In that the signal disc is fixed to the output element in a rotationally fixed manner, the rotational movement of the output element, and thus the pedaling frequency of the bicycle, can be determined particularly precisely.

Preferably, the drive assembly further comprises an output interface that is connected to the output element in a rotationally fixed manner by way of an output connection. In particular, a so-called chainring spider can be considered as an output interface. Preferably, the output interface is directly connected in a rotationally fixed manner to a pedal shaft. In particular, an output connection is considered to be a mechanical, preferably releasable, connection of the output element and the output interface. For example, the output connection includes a screw connection of the output element and the output interface. Due to the fact that the signal element is attached to the output element by way of the output connection, a particularly simple and inexpensive design with few components can be made possible.

Particularly preferably, the output connection comprises at least one screw sleeve and at least one screw. The screw sleeve is preferably arranged on the side of the output interface and the screw on the side of the output element. The screw is in particular screwed into the screw sleeve by way of a thread. Preferably, the signal element is attached by way of at least one further screw, which is screwed directly into the screw sleeve. The screw sleeve preferably comprises exactly one internal thread, in which the screw for attaching the output element and the screw for attaching the signal element are screwed from different directions. Alternatively preferably, the screw sleeve for the two screws of the output element or signal element each comprise a separate thread. Further alternatively, preferably, the sensor element is attached by way of at least one clip, which is inserted into the screw sleeve. The clip can have a one-part or multi-part design. This allows a precise and robust attachment of the signal element in a simple and cost-effective manner.

Particularly preferably, the drive assembly comprises the sensor assembly described above. By way of the sensor of the sensor assembly, the movement of the signal element, and thus the movement of the output element, can be detected relative to the immovably arranged sensor assembly in order to be able to determine the pedaling frequency of the bicycle in a particularly precise manner.

Preferably, a sensor axis of the sensor is arranged parallel to an output axis of the output element. Alternatively preferably, the sensor axis of the sensor is arranged obliquely to the output axis of the output element, in particular at an angle of at least 30° and maximum 60°, preferably 45°, to the output axis. Alternatively or additionally, a signal surface of the signal element, in particular one that can be scanned by the sensor, is preferably arranged orthogonally to the output axis of the output element. Alternatively preferably, the signal surface of the signal element is arranged obliquely to the output axis of the output element, in particular wherein a normal on the signal surface is arranged at an angle of at least 30° and a maximum of 60°, preferably 45°, to the output axis. Alternatively preferably, the signal surface of the signal element is arranged concentrically to the output axis of the output element. In that case, preferably, the sensor is arranged such that a sensor axis is orthogonal to the output axis.

Further preferably, the drive assembly further comprises a frame interface of a bicycle frame, the sensor mount being arranged within a frame opening of the frame interface. The frame opening is in particular in the form of a recess, preferably a bore. In particular, the sensor mount comprises a sleeve-shaped first holding element and a sleeve-shaped second holding element for holding the sensor. Thus, an alternative simple and inexpensively manufacturable and mountable attachment of the sensor to the bicycle can be provided.

Furthermore, the disclosure relates to a bicycle, in particular an electric bicycle, comprising the described drive assembly. Preferably, the bicycle comprises a hub drive, which is in particular arranged on a rear wheel hub of the bicycle. Further preferably, the bicycle comprises a control unit configured to control the hub drive, wherein the control unit is configured to control the hub drive depending on a pedaling frequency detected by the sensor assembly.

### BRIEF DESCRIPTION OF THE DRAWINGS

Exemplary embodiments of the disclosure are explained in detail below with reference to the accompanying drawings. The drawing shows:

FIG. 1 a simplified schematic view of an electric bicycle with a drive assembly according to a first exemplary embodiment of the disclosure,

FIG. 2 a detail view of the drive assembly of the first exemplary embodiment,

FIG. 3 a detail view of the drive assembly of the first exemplary embodiment,

FIG. 4 an exploded view of a detail of the drive assembly of the first embodiment,

FIG. 5 a perspective detail of a sensor assembly of a drive assembly according to a second exemplary embodiment of the disclosure,

FIG. 6 a sectional view of the detail of FIG. 5,

FIG. 7 a further sectional view of the detail of FIG. 5,

FIG. 8 a detail sectional view of the drive assembly of the first exemplary embodiment,

FIG. 9 a detailed sectional view of a drive assembly according to a third exemplary embodiment of the disclosure,

FIG. 10 a detail sectional view of a drive assembly according to a fourth exemplary embodiment of the disclosure,

FIG. 11 a detailed view of a drive assembly according to a fifth exemplary embodiment of the disclosure,

FIG. 12 a detailed view of a drive assembly according to a sixth exemplary embodiment of the disclosure.

FIG. 13 a sectional view of the drive assembly of FIG. 12,

FIG. 14 an exploded view of a sensor assembly of the drive arrangement of FIG. 12,

FIG. 15 a detailed view of a drive assembly according to a seventh exemplary embodiment of the disclosure,

FIG. 16 a sectional view of a detail of the drive assembly of FIG. 15, and

FIG. 17 an exploded view of a detail of a sensor assembly of the drive assembly of FIG. 15.

### DETAILED DESCRIPTION

Preferably, all identical components, elements, and/or units are provided with the same reference symbols in all figures.

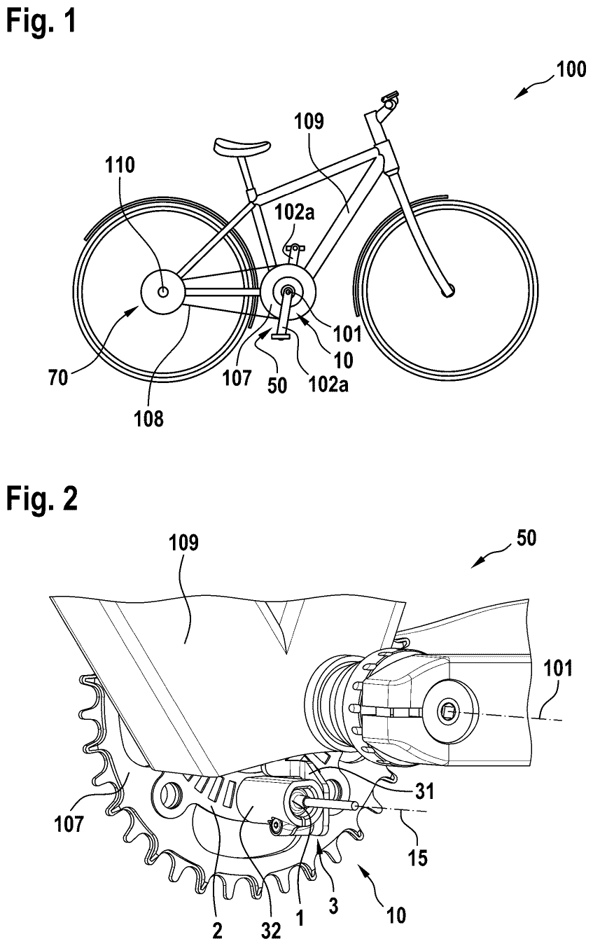

FIG. 1 shows a simplified schematic view of a bicycle 100 with a drive assembly 50 according to a first exemplary embodiment of the disclosure. Details regarding the drive assembly 50 of the first exemplary embodiment are shown in FIGS. 2 to 4 and FIG. 8.

The bicycle 100 is an electric bicycle 100.

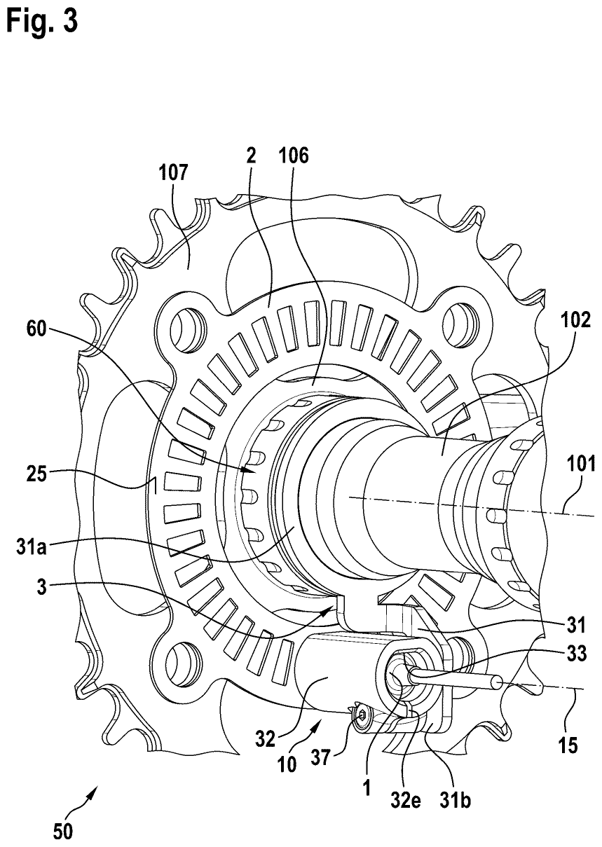

The drive unit 50 is arranged in the region of a bottom bracket of the electric bicycle 100. The bottom bracket (not visible) is located within a bottom bracket assembly 60 (cf. FIG. 3). The bottom bracket is configured to store a pedal shaft 102, which is in particular connectable in a rotationally fixed manner to cranks 102a. By way of the cranks 102a, a rider of the electric bicycle 100 can apply a muscle-generated pedal force on the drive of the electric bicycle 100.

The drive assembly 50 includes a hub drive 70 on a rear hub 110 of the electric bicycle 100. The hub drive 70 in particular includes a motor on the rear wheel hub 110. A motor torque generated by the motor may be transmitted, preferably via a transmission, to the rear wheel hub 110 and thus the rear wheel of the electric bicycle 100 to have motor support of the rider's pedaling force. The motor of the hub drive 70 is preferably an electric motor, which can be supplied with electrical energy by way of an electrical energy store of the electric bicycle 100.

In addition, the rear wheel hub is connected to the crank mechanism via a transmission element 108, which is preferably configured as a bicycle chain. In detail, the crank mechanism includes an output element 107, which is in particular configured as a chainring, which engages with the transmission element 108. The rider pedal torque applied to the cranks 102a may be transmitted via the pedal shaft 102 and via an output interface 106 (cf. FIG. 3) at the output element 107. Preferably, cranks 102a and pedal shaft 102 and output interface 106 and output element 107 are connected in a rotationally fixed manner to each other.

The drive assembly 50 further comprises a sensor assembly 10, by way of which a pedaling frequency of the electric cycle 100 can be detected. A rotational speed of the rotational movement of the cranks 102 is considered to be a pedaling frequency. In particular, due to the rotationally fixed connection, the pedaling frequency corresponds to a rotational speed of the pedal shaft 102 and the output interface 106 and the output element 107, respectively.

The sensor assembly 10 is arranged on the crank mechanism of the electric bicycle 100.

The sensor assembly 10 comprises a signal element 2, which is configured as a signal disc, in detail as a perforated disc.

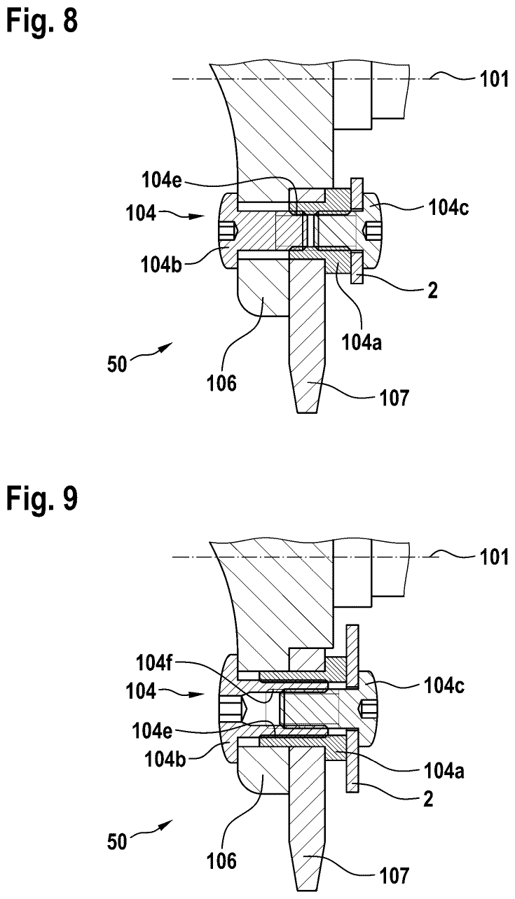

The signal element 2 is attached to the output element 107 in a rotationally fixed manner. The exact type of attachment will be described further below with respect to FIG. 8. The signal element 2 thus integrally rotates with the output element 107.

The signal element 2 is configured as a flat disk, which is arranged orthogonal to the pedal axis 101. That is, a signal surface 25 scanned by the sensor 1 and through which the holes extend is arranged orthogonal to the pedal axis 101.

In addition, the sensor assembly 10 comprises the sensor 1 and a sensor mount 3.

The sensor 1 is configured as a magnetoresistive sensor, which has a sensor axis 15 along which the sensor 1 is sensitive.

The sensor 1 is thereby held by the sensor mount 3 such that the sensor axis 15 is parallel to the pedal axis 101 and that the sensor axis 15 is at the height of the signal surface 25 of the signal element 2. In other words, the signal element 2 is scanned at the signal surface 25 with the holes through the sensor 1 orthogonal along the sensor axis 15.

The sensor 1 can thus detect the relative movement of the signal element 2 based on the magnetoresistive principle, whereby the pedaling frequency can be determined.

By way of the specific detection using a perforated disc and magnetoresistive sensor 1, the direction of movement of the signal element 2 can be detected in addition to the pedaling frequency. That is, a distinction may be made between forward rotation and reverse rotation.

The sensor mount 3 is configured in two parts and comprises a first holding element 31 and a second holding element 32.

The first holding element 31 has an annular attachment region 31a by way of which the sensor holder 3 is attached to the bottom bracket assembly 60 of the electric bicycle 100 coaxial to the output shaft 102. The annular attachment region 31a comprises an axial wall thickness of a bottom bracket spacer disc. In detail, the annular attachment region 31a is arranged on the output shaft 102 and is located directly adjacent to the bottom bracket and thereby replaces the function of the bottom bracket spacer, which can in particular be previously removed. By this, a particularly simple integration of the sensor assembly 10 into existing systems can be carried out without modification of the drive assembly 50.

Preferably, the annular attachment region 31a is clamped between the bottom bracket assembly 60, particularly a housing region of the bottom bracket assembly 60 fixed relative to the bicycle frame 109, and a portion of the bicycle frame 109, such that the first holding element 31 is fixed to the bicycle frame 109 in a fixed manner.

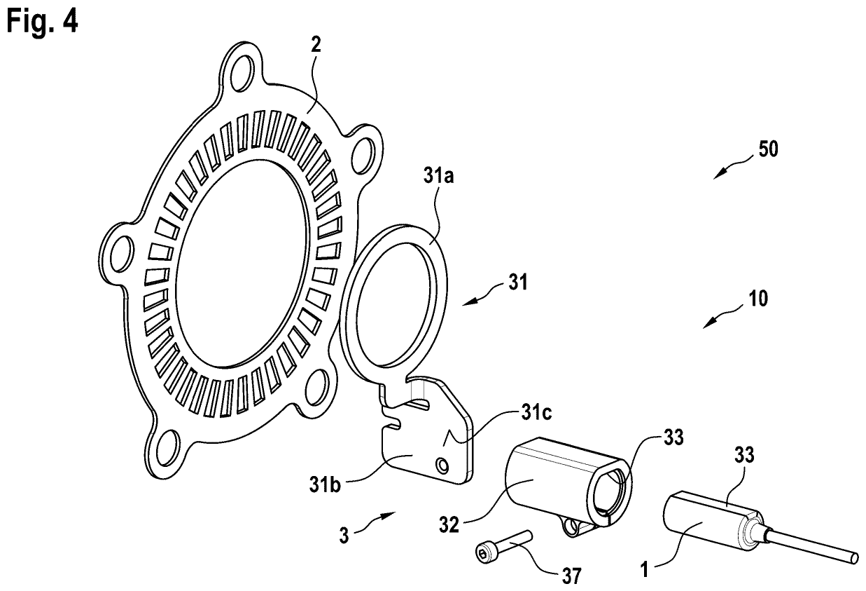

The first holding element 31 is configured as an angled sheet. In detail, the first holding element 31 comprises a web extending in a radial direction from the annular attachment region 31a, on which an angled holding region 31b is adjacent. The holding region 31b has an abutment surface 31c, which is orthogonally aligned with the annular attachment region 31a (cf. FIG. 4).

In the mounted assembly, the holding region 31b extends substantially downward in the vertical direction.

On the abutment surface 31c of the holding region 31b, the second holding element 32 is connected by way of a screw connection 37 (cf. FIGS. 3 and 4).

The second holding element 32 is configured as a sleeve within which the sensor 1 is held. In detail, the second holding element 32 comprises a longitudinal and radial slot 32e (cf. FIG. 3), which can be compressed by way of the screw connection 37 in order to cause the clamping of the sensor 1 in the interior.

In the unclamped state, the second holding element 32 allows for axial displacement of the sensor 1 along the sensor axis 15. An axial distance between sensor 1 and signal element 2 can thus be adjusted particularly flexibly and precisely.

The second holding element 32 and the sensor 1 also comprise positive locking elements 33, which interlock in a positive manner with respect to a circumferential direction of the second holding element 32 in order to position the sensor 1 in a defined rotational manner. That is to say, the positive locking elements 33 form an anti-rotation device of the sensor 1. On the sensor 1, the corresponding positive locking element 33 is configured as a flat section of the jacket surface of the sensor 1. By this, an accurate positioning and reliable mounting of the sensor 1 can be made in a particularly simple manner.

In FIG. 8, a detail sectional view of the attachment of the signal element 2 to the output element 107 is shown. The attachment is carried out by way of the screw connection, by way of which the output element 107 is screwed to the output interface 106.

In particular, this screw connection is part of an output connection 104 that connects the output element 107 to the output interface 106 in a rotationally fixed manner. The output connection 104 comprises a screw sleeve 104a, which is arranged on the side of the output element 107. In addition, the output connection 104 includes a screw 104b that is screwed into the screw sleeve 104a from the side of the output interface 106.

By way of an additional further screw 104c, the signal element 2 is screwed to the screw sleeve 104a. The two screws 104b and 104c are screwed together into a thread 104e of the screw sleeve 104a.

The output screw connection 104 shown in FIG. 8 with the attachment of the signal element 102 is in particular configured several times, preferably exactly four times, around the circumference of the output element 107.

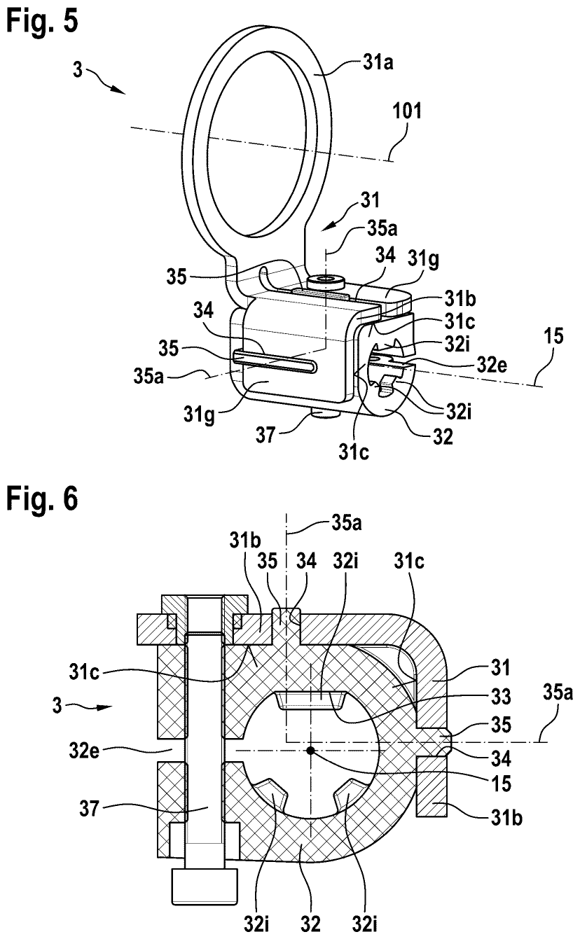

FIG. 5 shows a perspective view of a detail of a sensor holder 3 of a sensor assembly 10 of a drive assembly 50 according to a second exemplary embodiment of the disclosure. The second exemplary embodiment essentially corresponds to the first exemplary embodiment, with the difference being an alternative design of the sensor holder 3.

In the second exemplary embodiment, the first holding element 31 is configured as a bi-angled sheet. The annular attachment region 31a and precisely two attachment regions 31b are each orthogonally aligned with each other. The two attachment regions 31b each have an abutment surface 31c, wherein the two abutment surfaces 31c are arranged orthogonal to each other and parallel to the sensor axis 15, that is to say, in particular tangential to the sensor axis 15.

In each of the two attachment regions 31b, a recess 34 is configured in the form of a groove.

The two recesses 34 are each configured open towards the signal element 2. In addition, the recess 34 is axially open on both sides in the upper attachment region 31b, which is connected to the annular attachment region 31a.

Due to the open recesses 34, the respective attachment region 31b has flexible spring region 31g adjacent to the side facing away from the other attachment region 31 b, which is elastically flexible.

The second holding element 32 further has abutment surfaces arranged orthogonal to each other, corresponding to the abutment surfaces 31c of the first holding element 31.

In addition, the second holding element 32 comprises two protruding wing elements 35, which are configured to be able to engage in the recesses 34.

Due to the specific construction and geometry of the recesses 34 and wing elements 35, the sensor mount 3 in the second exemplary embodiment can be mounted completely relative to one another without axial movement of the holding elements 31 and 32. In detail, the second holding element 32 can be mounted on the first holding element 31 purely in a radial and/or tangential direction and/or with rotating motion. For this purpose, precisely one of the wing elements 35 can first be inserted into one of the recesses 34. The second holding element 32 is then rotated accordingly and clipped into the second recess 34 by way of the second wing element 35. This is made possible by the elastic resiliency of the spring regions 31d.

This makes it particularly advantageous to mount the second holding element 32 if the first holding element 31 is already attached to the bottom bracket assembly 60, thereby preventing, for example, insertion from the axial direction from the side of the output element 107.

Furthermore, in the second exemplary embodiment, the second holding element 32 comprises axial securing elements 32i which are formed radially in the opening protruding on an axial end of the second holding element 32 that faces away from the output element 107. These axial securing elements 31i cause a limitation of the axial displaceability of the sensor 1 rearward and can thus prevent the sensor 1 from falling out of the second holding element 32.

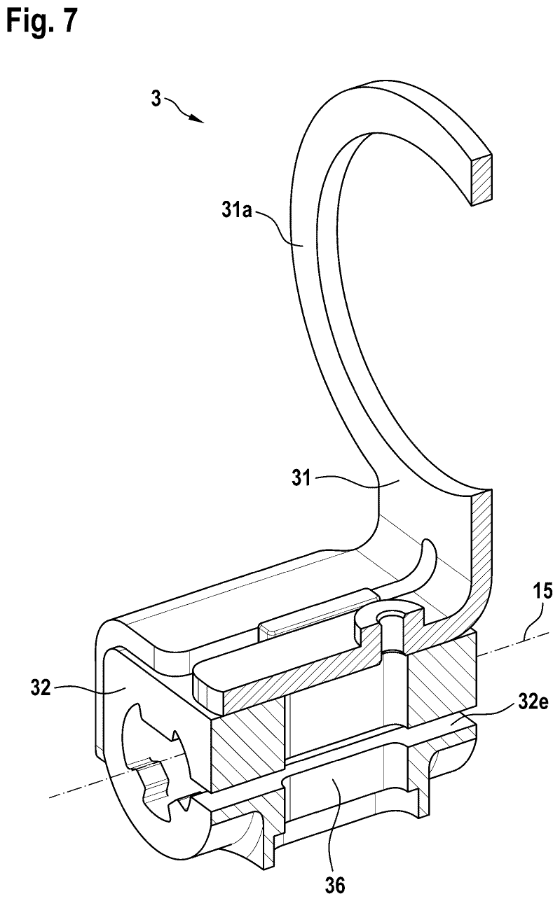

In the second exemplary embodiment, the second holding element 32 also comprises an oblong hole 36 within which the fixing element 37 of the screw connection is arranged (cf. FIG. 7). The oblong hole 36 has an extension along a direction parallel to the sensor axis 15, whereby the second holding element 32 can be slidably attached axially relative to the first holding element 31. By this, in addition to the axial displaceability of the sensor 1 within the second holding element 32, an even greater axial clearance of the positioning of the sensor 1 relative to the signal element 2 can be provided.

FIG. 9 shows a detailed sectional view of a drive assembly 50 according to a third exemplary embodiment of the disclosure. The third exemplary embodiment substantially corresponds to the first exemplary embodiment, with the difference being an alternative screw connection of the signal element 2. In the third exemplary embodiment of FIG. 9, the screw 104b on the side of the output interface 106 is configured as a hollow screw with a thread in which the screw 104c of the signal element 2 is screwed. That is to say, in this case, the screw 104c on the side of the signal element 2 is not screwed into the screw sleeve 104a but into the internal thread 104f of the screw 104b. An alternative, robust and simple and efficient screw connection can thus be provided.

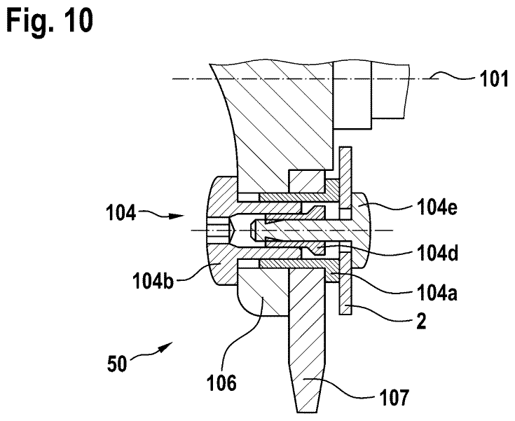

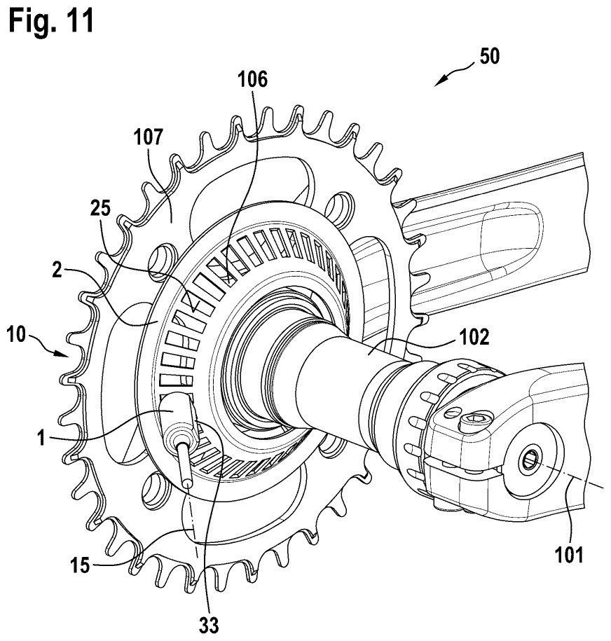

FIG. 10 shows a detail sectional view of a drive assembly 50 according to a fourth exemplary embodiment of the disclosure. The fourth exemplary embodiment substantially corresponds to the first exemplary embodiment, with the difference being a further alternative attachment of the signal element 2. In the fourth exemplary embodiment of FIG. 10, the signal element 2 is attached by a clip 104d, which is inserted into the screw sleeve 104a. In detail, the clip 104d can be configured as a spreading element, which is radially widened by a pin 104e and thereby causes a clamping connection. The pin 104e holds the signal element 2 to the screw sleeve 104a. By this, a further alternative, robust and particularly simple and time-efficient attachment of the signal element 2 to be produced can be enabled.

It should be noted that the attachment options of the signal element 2 described in FIGS. 8 to 10 can be combined in any way with any of the further design variants of the sensor mount 3.

FIG. 11 shows a perspective detailed view of a drive assembly 50 according to a fifth exemplary embodiment of the disclosure. The fifth exemplary embodiment substantially corresponds to the first exemplary embodiment, with the difference being an alternative alignment of the sensor 1 and signal element 2. In the fifth exemplary embodiment of FIG. 11, the sensor axis 15 is arranged obliquely to the output axis 101, in particular substantially at an angle of about 30°. The signal surface 25 of the signal element 2 is also arranged obliquely to the normal plane with respect to the output axis 101.

In particular, the signal surface 25 of the signal element 2 is configured in the form of a conical jacket surface.

By this, an alternative arrangement of the components of the drive assembly 50 may be provided with the same function. Thus, for example, a more flexible arrangement can be enabled in confined spaces.

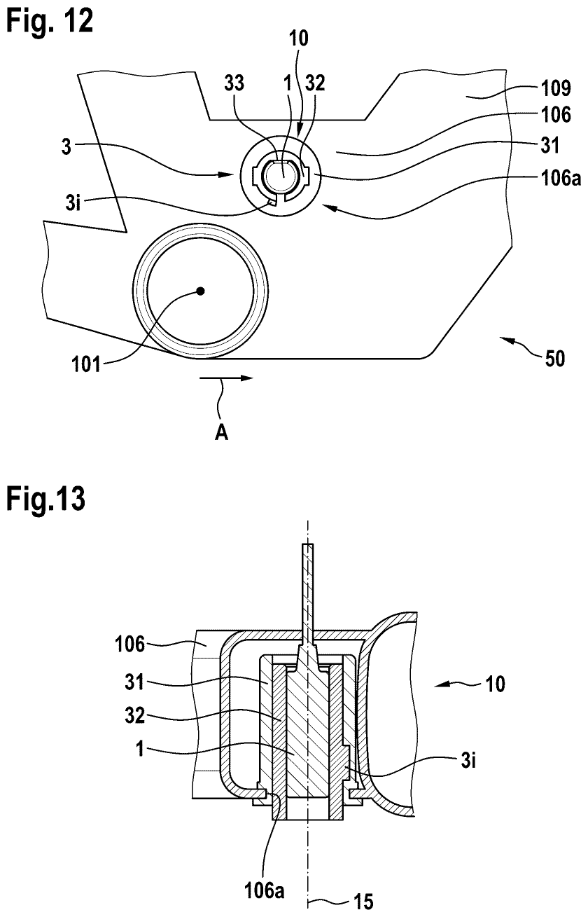

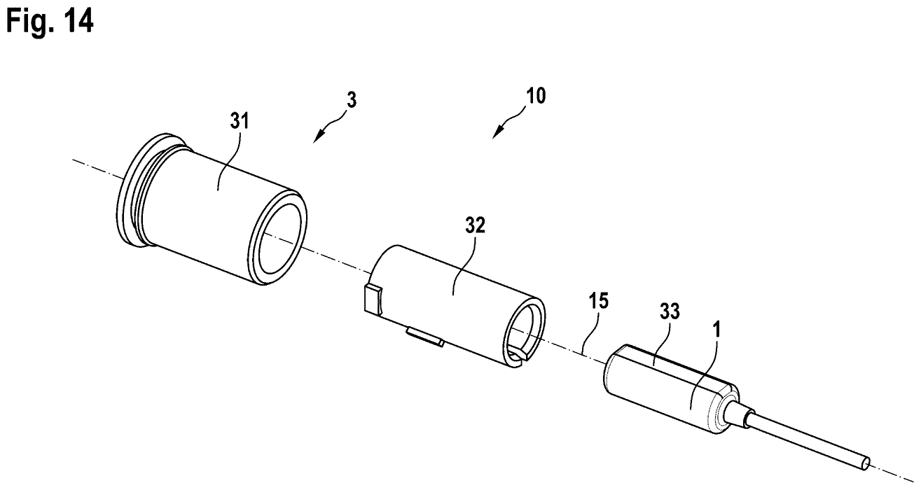

FIG. 12 shows a detailed view of a drive assembly 50 according to a sixth exemplary embodiment of the disclosure. Further detailed views of the drive assembly 50 of the sixth exemplary embodiment are shown in FIGS. 13 and 14. The sixth exemplary embodiment essentially corresponds to the first exemplary embodiment, with the difference being an alternative design and arrangement of the sensor holder 3. In the sixth embodiment, the sensor mount 3 is directly integrated into a frame opening 106a of a frame interface 106 of the bicycle frame 109. The frame interface 106 is located near the drive axis 101, preferably in front of it in the direction of travel A and vertically above the output axis 101.

In the sixth embodiment, the first holding element 31 is also configured as a sleeve, which is configured to be attachable in the frame opening 106.

Preferably, a connection 31i in the form of a bayonet connection is formed between the first holding element 31 and the second holding element 32. This allows a robust and reliable holder to be made with ease and time-efficient assembly.

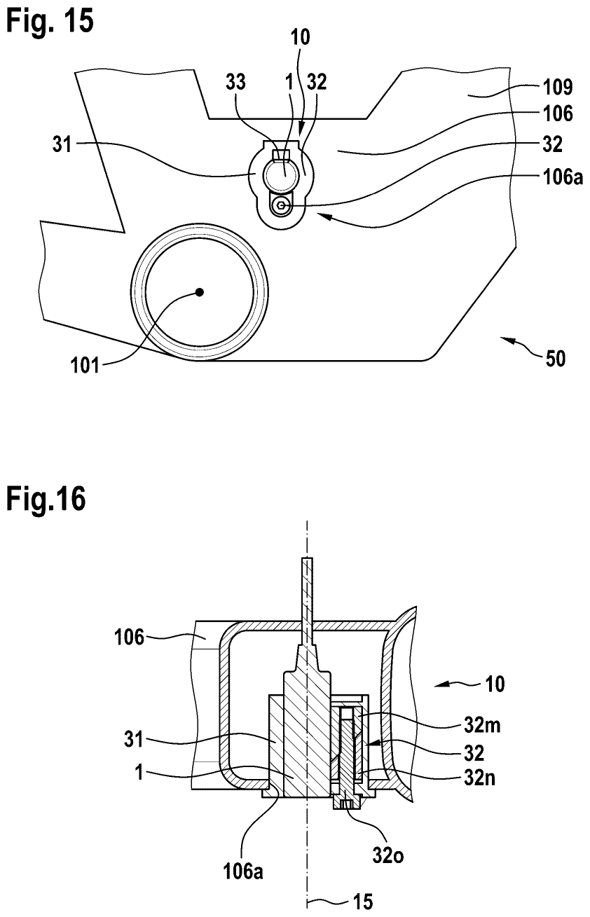

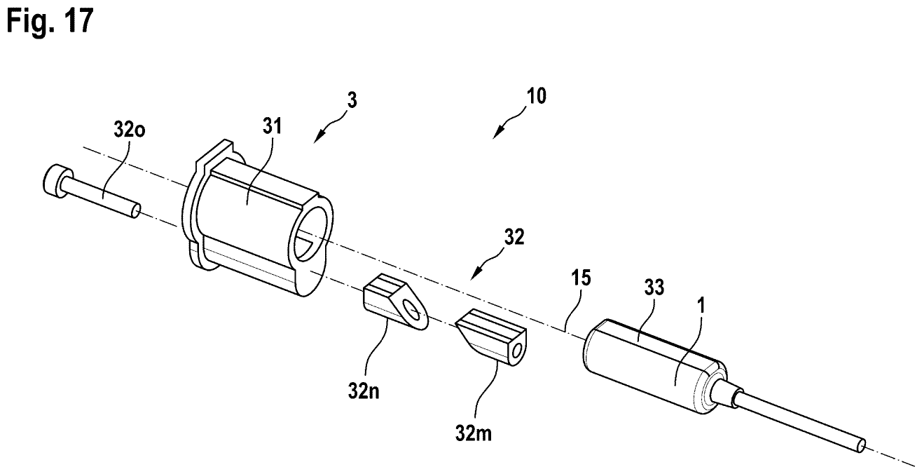

FIG. 15 shows a detailed view of a drive assembly 50 according to a seventh exemplary embodiment of the disclosure. Further detailed views of the seventh exemplary embodiment are shown in FIGS. 16 and 17. The seventh exemplary embodiment substantially corresponds to the sixth exemplary embodiment of FIG. 12, with an alternative design of the first holding element 31 and second holding element 32.

In the seventh embodiment, the sensor 1 is arranged directly in the first holding element 31. The second holding element 32 is arranged radially adjacent to the sensor 1.

The second holding element 32 is formed from two clamping wedges 32m and 32n, which can be screwed against one another by a screw 32o parallel to the sensor axis 15, whereby a radial clamping force is applied to the sensor 1 by sliding the wedges to one another (cf. FIGS. 16 and 17). By this, a particularly robust clamping of the sensor 1 can be made possible in a simple and cost-efficient manner.

What is claimed is:

1. A sensor assembly for detecting a pedaling frequency of a bicycle, comprising:
a sensor, and
a sensor mount for holding the sensor,
wherein the sensor is configured to detect a relative movement of a signal element to the sensor,
wherein the sensor mount comprises a first holding element and a second holding element,
wherein the first holding element is configured to be attached to the bicycle,
wherein the second holding element is attached to the first holding element, and
wherein the second holding element is configured to hold the sensor.

2. The sensor assembly according to claim 1, wherein the sensor is substantially cylindrical and comprises an anti-rotation device.

3. The sensor assembly according to claim 2, wherein the sensor and the second holding element each comprise positive locking elements that interlock positively with respect to a circumferential direction of the second holding element for rotational positioning of the sensor.

4. The sensor assembly according to claim 1, wherein:
the first holding element comprises an annular attachment region by way of which the sensor bracket is coaxially attachable to an output shaft at a bottom bracket assembly of the bicycle, and
the annular attachment region comprises an axial wall thickness of a bottom bracket spacer.

5. The sensor assembly according to claim 1, wherein the first holding element is configured as a multiple angled component.

6. The sensor assembly according to claim 1, wherein:
the first holding element comprises two recesses, and
the second holding element comprises two protruding wing elements engaging in the recesses.

7. The sensor assembly according to claim 1, wherein the second holding element is attached to the first holding element by way of an oblong hole and a fixing element arranged in the oblong hole.

8. The sensor assembly according to claim 1, wherein the second holding element is configured for radial, clamping attachment of the sensor.

9. A drive assembly of a bicycle, comprising:
an output element configured to engage with a transmission element of the bicycle; and
a signal element attached to the output element in a rotationally fixed manner,
wherein the signal element is configured as a signal disc.

10. The drive assembly according to claim 9, further comprising an output interface connected in a rotationally fixed manner to the output element by way of an output connection,
wherein the signal element is attached to the output element by way of the output connection.

11. The drive assembly according to claim 10, wherein the output connection comprises at least one screw sleeve and at least one screw, wherein:
the signal element is attached by way of at least one further screw which is screwed directly into the screw sleeve, or
the signal element is attached by way of at least one clip which is inserted into the screw sleeve.

12. The drive assembly according to claim 10, further comprising a sensor assembly.

13. The drive assembly according to claim 12, wherein:
a sensor axis of the sensor is arranged parallel to an output axis of the output element, or the sensor axis of the sensor is arranged obliquely to the output axis of the output element, and/or
a signal surface of the signal element is orthogonal to the output axis of the output element, or the signal surface of the signal element is arranged obliquely to the output axis of the output element, or the signal surface of the signal element is arranged concentrically to the output axis of the output element.

14. The drive assembly according to claim 10, further comprising a frame interface of a bicycle frame, wherein the sensor mount is arranged within a frame opening of the frame interface.

15. An electric bicycle, comprising:
the sensor assembly according to claim 1; and
a hub drive at a rear wheel hub of the electric bicycle.

16. The sensor assembly according to claim 5, wherein the multiple angled component is made of sheet metal.

17. The sensor assembly according to claim 5, wherein the multiple angled component comprises at least two orthogonal contact surfaces.

18. The sensor assembly according to claim 6, wherein:
the recesses are arranged at orthogonal holding regions of the first holding element, and
the wing elements extend along wing axes that are orthogonal to each other.

19. The drive assembly according to claim 9, wherein the signal disc is perforated.

20. An electric bicycle, comprising:
the drive assembly according to claim 9; and
a hub drive at a rear wheel hub of the electric bicycle.
